(19) United States
(12) Patent Application Publication
(10) Pub. No.: US 2025/0143195 A1
(43) Pub. Date: May 1, 2025

(54) Non-Volatile Memory with Oxygen Scavenger Regions and Methods of Making the Same

(71) Applicant: Nanyang Technological University, Singapore (SG)

(72) Inventors: Yuanmin DU, Singapore (SG); Wen Siang LEW, Singapore (SG); Putu Andhita DANANJAYA, Singapore (SG); Siew Wei HOO, Singapore (SG)

(73) Assignee: Nanyang Technological University, Singapore (SG)

(21) Appl. No.: 18/692,088

(22) PCT Filed: Sep. 23, 2022
(86) PCT No.: PCT/SG2022/050688

§ 371 Date: Mar. 14, 2024

(30) Foreign Application Priority Data
Sep. 23, 2021 (SG) 10202110532Y

(51) Int. Cl. H10N 70/00; H10B 63/00

(52) U.S. Cl. CPC H10N 70/8833; H10B 63/80; H10N 70/021; H10N 70/841

(57) ABSTRACT

A non-volatile memory includes: a buffer region in direct contact with a first electrode; and a principal memory region between the second electrode and the buffer region. The principal memory region includes: a first active region disposed in direct contact with the buffer region; a second active region with a second oxygen concentration that is lower than a first oxygen concentration of the first active region; a first scavenger region formed with a third oxygen concentration that is lower than the second oxygen concentration; and a second scavenger region disposed in direct contact with the second electrode, the second scavenger region being formed with a fourth oxygen concentration. Each of the second active region and the second scavenger region is disposed in direct contact with the first scavenger region, the second active region and the second scavenger region being formed physically spaced apart from one another.

The present application claims priority to the Singapore patent application no. 10202110532Y, the entire disclosure of which is incorporated herein by reference.

### TECHNICAL FIELD

The present disclosure relates to the field of non-volatile memories, and more particularly to resistive random-access memories and methods of fabricating the same.

### BACKGROUND

Non-volatile memories (NVM) such as resistive random-access memories (RRAM) store data based on a change in the electrical resistance of a main switching layer. Such devices are useful in many applications, for example, in logic circuits, as memory components, and for communication between logic devices and memory devices, etc. Various manufacturing processes, such as those in the Back-End-of-Line (BEOL) semiconductor manufacturing processes, may subject the NVM film stack to relatively high temperatures. Unfortunately, the performance of some NVM configurations suffered after being over heated. There is therefore a need for a more robust NVM film stack.

### SUMMARY

In one aspect, the present application discloses a non-volatile memory device. The non-volatile memory device includes a first electrode, a second electrode, a buffer region, and a principal memory region. The second electrode is formed of a second electrode material. The buffer region is disposed in direct contact with the first electrode. The principal memory region is disposed between the second electrode and the buffer region. The principal memory region includes a first active region, a second active region, a first scavenger region, and a second scavenger region. The first active region is disposed in direct contact with the buffer region, in which the first active region is formed with a first oxygen concentration. The second active region is formed with a second oxygen concentration that is lower than the first oxygen concentration. The first scavenger region is formed with a third oxygen concentration that is lower than the second oxygen concentration. The second scavenger region is disposed in direct contact with the second electrode, in which the second scavenger region is formed with a fourth oxygen concentration. Each of the second active region and the second scavenger region is disposed in direct contact with the first scavenger region. The second active region and the second scavenger region are formed physically spaced apart from one another.

A first interface between the first active region and the second active region may be characterized by a first oxygen gradient, in which the first oxygen gradient corresponds to a difference between the first oxygen concentration and the second oxygen concentration. A second interface between the second active region and the first scavenger region may be characterized by a second oxygen gradient, in which the second oxygen gradient corresponds to a difference between the second oxygen concentration and the third oxygen concentration. A third interface between the first scavenger region and the second scavenger region is characterized by a third oxygen gradient, in which the third oxygen gradient corresponds to a difference between the third oxygen concentration and the fourth oxygen concentration. The second oxygen gradient is configured to be steeper than at least one of the first oxygen gradient and the third oxygen gradient.

The second oxygen gradient may be configured to be steeper than each of the first oxygen gradient and the third oxygen gradient.

The first oxygen concentration and the second oxygen concentration may define a first range of oxygen concentrations. The third oxygen concentration and the fourth oxygen concentration may define a second range of oxygen concentrations. The second range of oxygen concentrations is lower than the first range of oxygen concentrations. The first range of oxygen concentrations and the second range of oxygen concentrations are non-overlapping and distinct from one another.

The principal memory region may be characterized by a monotonic oxygen profile having at least a first range of oxygen concentrations and a second range of oxygen concentrations. The monotonic oxygen profile may be characterized by a step decrease in oxygen concentration from the first range of oxygen concentrations to the second range of oxygen concentrations.

The third oxygen concentration may be higher than the fourth oxygen concentration. The third oxygen concentration may be near-zero, and the fourth oxygen concentration may be zero.

The buffer region is formed of a first metal oxide. The first metal oxide may comprise at least one of MgO, AlOₓ₁, SiOₓ₁, CaO, LaAlO₃, HfSiOₓ₁, or any combination thereof.

The first active region comprises a second metal oxide formed with a stoichiometric material composition or a near-stoichiometric material composition. The first active region may comprise one of a Ta oxide, a Ti oxide, a Hf oxide, a Zr oxide, a Sr oxide, a La oxide, a W oxide, a V oxide, or any combination thereof. The first active region may comprise Ta₂Oₓ in which 4<x<5.

The second active region comprises a third metal oxide. The second active region may comprise TaO_{y} in which 1.5<y<x.

The first scavenger region comprises a fourth metal oxide. The first scavenger region may comprise TaO_{z} in which 0<z<0.5.

The second scavenger region may be formed of an active metal, in which the active metal is selected to have a work function smaller than that of the second electrode material. The second scavenger region may comprise at least one of Ta, Ti, Hf, Zr, Co, Ni, Fe, or any alloy thereof.

The first active region may comprise Ta₂Oₓ in which 4.5≤x≤5. The second active region may comprise TaO_{y} in which 1.5≤y≤2.2. The first scavenger region may comprise TaO_{z} in which 0<z≤0.3.

The first electrode may comprise one of a metal, a metal alloy, and a conductive nitride. The first electrode may comprise at least one of Pt, Pd, Au, Al, W, Cu, Mo, Co, Ni, Fe, Ir, Ru, Rh, TiN, TiW, TaW, and TaN. The second electrode may comprise at least one of Pt, Pd, Au, Ir, Ru, Rh, TiN, and TaN.

Preferably, the first electrode comprises W, the buffer region comprises Al₂O₃, the first active region comprises Ta₂O₅, the second active region comprises TaO₂, the second scavenger region comprises Ta, and the second electrode comprises Pt, wherein the first scavenger region comprises TaO_{z} in which 0<z≤0.3.

Preferably, the buffer region comprises Al₂O₃, and the first active region comprises Ta₂Oₓ in which 4.5≤x≤5.

Preferably, the second active region comprises TaO_{y} in which 1.5≤y≤2.2, and in which the second active region is doped with a first dopant, the first dopant being a metal different from any metal present in the first active region. Preferably, the first scavenger region comprises TaO_{z} in which 0<z≤0.3, and in which the first scavenger region is doped with a second dopant. The second dopant may be a metal different from any metal present in the first active region. In some embodiments, the second dopant may be a metal that is the same as any one metal present in the second active region, and in some embodiments the second dopant may be a metal different from any metal present in the second active region.

Each of the first active region and the second active region may comprise an oxide of a same group, in which the second active region is one of an undoped third metal oxide and a doped third metal oxide, and in which the doped third metal oxide is doped with a first dopant, the first dopant being a metal different from a metal element of the oxide of the first active region.

Each of the second active region and the first scavenger region may comprise an oxide of a same group, in which the first scavenger region is one of an undoped fourth metal oxide and a doped fourth metal oxide, and in which the doped fourth metal oxide is doped with a second dopant. The second dopant may be a metal different from a metal element of the oxide of the first active region. In some embodiments, the second dopant may be a metal that is the same as any one metal present in the second active region, and in some embodiments the second dopant may be a metal different from any metal present in the second active region.

Each of the first active region, the second active region, the first scavenger region, and the second scavenger region may have a film thickness in a range from 1 nanometer to 10 nanometers. The buffer region may have a film thickness in a range from 0.5 nanometer to 5 nanometers.

In another aspect, the present application discloses a method of making the non-volatile memory, the method comprising: disposing the first scavenger region on the second scavenger region before disposing the second active region on the first scavenger region; and disposing the first active region on the second active region such that the principal memory region is formed with four distinct regions of different oxygen concentrations.

In another aspect, the present application discloses a method of making the non-volatile memory, the method comprising: disposing the second active region on the first active region; and disposing the first scavenger region on the second active region before disposing the second scavenger region on the first scavenger region such that the principal memory region is formed with four distinct regions of different oxygen concentrations.

### BRIEF DESCRIPTION OF DRAWINGS

FIG. 1 is a schematic cross-sectional diagram of a non-volatile memory device according to one embodiment of the present disclosure;

FIGS. 2A and 2B schematically illustrate an exemplary operational resistive switching mechanism of a non-volatile memory device of FIG. 1;

FIG. 3A is a schematic diagram illustrating oxygen distribution across the principal memory region according to the embodiment of FIG. 1;

FIG. 3B is a graphical representation of an oxygen gradient in the principal memory region of FIG. 3A;

FIG. 4 is a cross-sectional view showing a specific stack according to an example of the embodiment;

FIG. 5 is a graph illustrating an exemplary current-voltage electroforming process of the stack of FIG. 4;

FIG. 6 is a graph illustrating the exemplary current-voltage curves of a non-volatile memory device with the stack of FIG. 4;

FIG. 7 shows the exemplary results of an endurance test performed on a non-volatile memory device with the stack of FIG. 4;

FIGS. 8A and 8B are schematic flow charts of embodiments of a method to fabricate the non-volatile memory device of FIG. 1; and

FIG. 9 is a schematic diagram illustrating a preferred embodiment of the method according to FIGS. 8A and 8B.

### DETAILED DESCRIPTION

Reference throughout this specification to “one embodiment”, “another embodiment” or “an embodiment” (or the like) means that a particular feature, structure, or characteristic described in connection with the embodiment is included in at least one embodiment. Thus, the appearance of the phrases “in one embodiment” or “in an embodiment” or the like in various places throughout this specification are not necessarily all referring to the same embodiment. Furthermore, the described features, structures, or characteristics may be combined in any suitable manner in one or more embodiments. In the following description, numerous specific details are provided to give a thorough understanding of embodiments. One skilled in the relevant art will recognize, that the various embodiments be practiced without one or more of the specific details, or with other methods, components, materials, etc. In other instances, some or all known structures, materials, or operations may not be shown or described in detail to avoid obfuscation.

The word “exemplary” is used herein to mean “serving as an example, instance, or illustration.” Any embodiment described herein as “exemplary” is not necessarily to be construed as preferred or advantageous over other embodiments. As used herein, the singular ‘a’ and ‘an’ may be construed as including the plural “one or more” unless apparent from the context to be otherwise.

Terms such as “first” and “second” are used in the description and claims only for the sake of brevity and clarity, and do not necessarily imply a priority or order, unless required by the context. The terms “about” and “approximately” as applied to a stated numeric value encompasses the exact value and a reasonable variance as will be understood by one of ordinary skill in the art, and the terms “generally” and “substantially” are to be understood in a similar manner, unless otherwise specified.

As used in the present disclosure, the term “non-volatile memory (NVM) device” refers to computer-accessible memory devices in which stored data can be retained even when the device is not powered on. Non-volatile memory devices in which embodiments of the present disclosure are applicable include, but are not limited to, resistive random-access memory (ReRAM) devices, phase-change random-access memory (PRAM), magnetic random-access memory (MRAM), voltage-controlled magnetic anisotropy (VCMA) devices, ferroelectric random-access memory (FRAM), flash memory devices, read-only memories (ROM), erasable programmable read-only memories (EPROM), electrically erasable programmable read-only memories (EEPROM), etc.

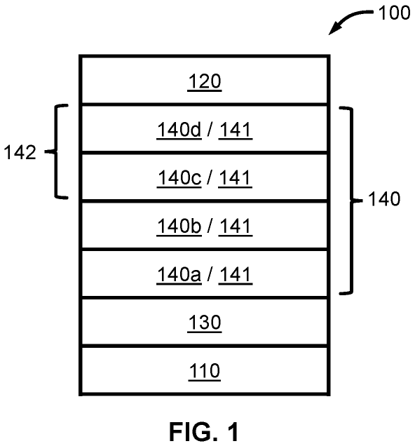

FIG. 1 provides a cross-sectional view of a non-volatile memory device 100 in accordance with embodiments of the present disclosure. In one exemplary embodiment, the non-volatile memory device 100 includes a first electrode 110, a second electrode 120, a buffer region 130, and a principal memory region 140. The buffer region 130 and the principal memory region 140 are disposed between the first electrode 110 and the second electrode 120. The principal memory region 140 has multiple active regions 141, including a first active region 140a, a second active region 140b, a first scavenger region 140c, and a second scavenger region 140d. The first scavenger region 140c and the second scavenger region 140d also serve as active regions 141 of the principal memory region 140. The first electrode 110 and the buffer region 130 are disposed in direct contact with one another. The second electrode 120 and the second scavenger region 140d are disposed in direct contact with one another.

The buffer region 130 is disposed between the first electrode 110 and the principal memory region 140. The buffer region 130 is disposed in direct contact with the first electrode 110, i.e., the buffer region 130 is immediately adjacent to and in direct physical contact with the first electrode 110. The buffer region 130 is disposed in direct contact with the principal active region 140. The whole of the buffer region 130 is spaced apart from the second electrode 120 by the principal memory region 140. The principal memory region 140 is disposed between the buffer region 130 and the second electrode 120. The principal memory region 140 is in direct contact with the second electrode 120, i.e., the principal memory region 140 is immediately adjacent to or in direct physical contact with the second electrode 120.

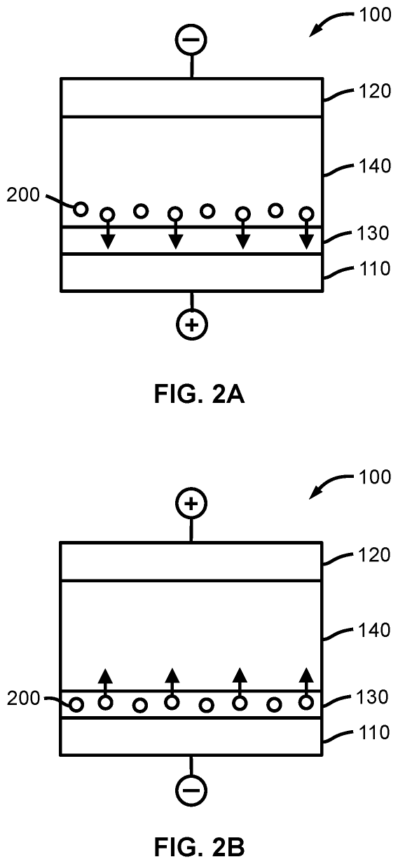

FIGS. 2A and 2B show cross-sectional views for describing an exemplary operational mechanism of the non-volatile memory device 100. As illustrated in FIG. 2A, when a negative voltage is applied to the second electrode 120, oxygen ions 200 migrate out of the principal memory region 140. A reduction process occurs, and the device is switched into an LRS (low resistance state). The voltage applied is defined as the SET voltage, that is, a SET process takes place. In comparison, FIG. 2B shows that the non-volatile memory device is switched into an HRS (high resistance state). In this example, when a positive voltage is applied to the second electrode 120, oxygen ions 200 migrate into the principal memory region 140, and an oxidation process takes place. The voltage applied is defined as the RESET voltage, and the process is called as a RESET process. With the non-volatile memory device continuously working between an LRS (an ON-state) and an HRS (an OFF-state), the non-volatile memory device works as an electrical switch.

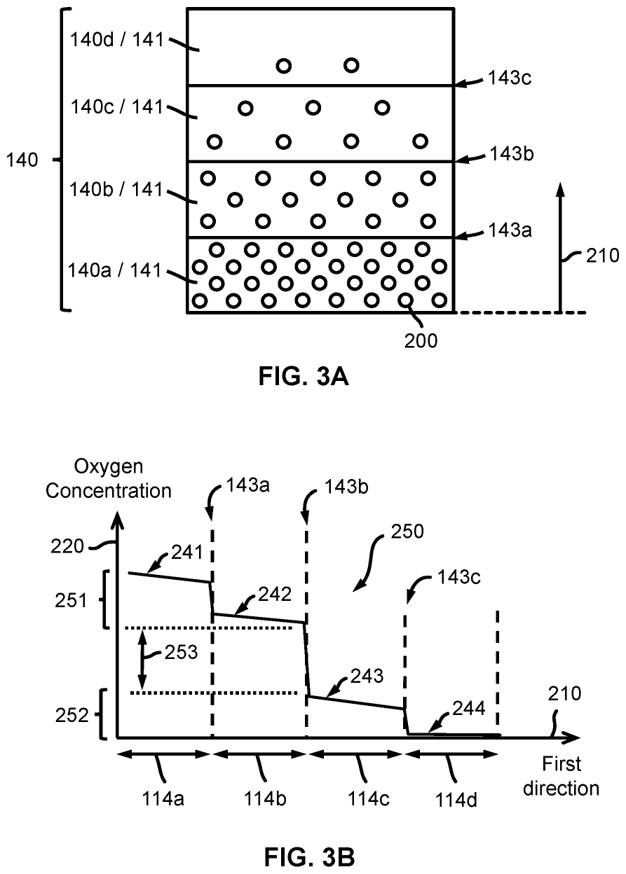

As illustrated schematically in FIG. 1 and FIG. 3A, in a preferred embodiment, the principal memory region 140 includes four active regions 141, mutually distinguishable from one another by their respective material compositions. In the present disclosure, the four active regions 141 are respectively referred to as the first active region 140a, the second active region 140b, the third active region 140c, and the fourth active region 140d. The non-volatile memory device 100 may be interchangeably referred to herein as a stack 100, a stack configuration, or a thin-film stack, regardless of the shape and configuration of each of the active regions 141 and/or the buffer region 130. For example, each of the four active regions 141 may be in the form of a thin film or a layer. For different non-volatile memory applications, each of the four active regions 141 need not be a strictly flat planar configuration.

The first active region 140a is disposed in direct contact with the buffer region 130. The second active region 140b is disposed in direct contact with the first active region 140a. The second active region 140b is wholly spaced apart from the buffer region 130, i.e., the second active region 140b is not in direct contact with the buffer region 130. The third active region 140c is disposed in direct contact with the second active region 140b. The third active region 140c is wholly spaced apart from the first active region 140a, i.e., the third active region 140c is not in direct contact with the first active region 140a. The fourth active region 140d is disposed in direct contact with third active region 140c. The fourth active region 140d is wholly spaced apart from the second active region 140b, i.e., the fourth active region 140d is not in direct contact with the second active region 140b.

The principal memory region 140 includes the first active region 140a, the second active region 140b, the third active region 140c in which the third active region 140c is an oxygen scavenger region relative to the second active region 140b, and the fourth active region 140d in which the fourth active region 140d is an oxygen scavenger region relative to the third active region 140c. In the present disclosure, the third active region 140c may be interchangeably referred to as a first scavenger region 140c, and the fourth active region 140d may be interchangeably referred to as a second scavenger region 140d. The principal memory region 140 may be described as including an oxygen scavenger region 142, in which the oxygen scavenger region 142 includes a first scavenger region 140c and a second scavenger region 140d. Each of the second active region 140b and the second scavenger region 140d is disposed in direct contact with the first scavenger region 140c. The second active region 140b and the second scavenger region 140d are formed physically spaced apart from one another. In other words, the second active region 140b and the second scavenger region 140d are never in physical contact with one another even in the course of fabricating the stack 100.

Adjacent or neighboring ones of the plurality of active regions 141 are mutually distinguishable from one another by their respective material composition. As illustrated by FIGS. 3A and 3B, the plurality of active regions 141 may be distinguishable from one another by their respective oxygen content or oxygen concentration. In the present disclosure, the terms “oxygen concentration” and “oxygen ion concentration” may be used interchangeably, and terms such as “oxygen gradient” etc. are to be understood in a similar manner. The principal memory region 140 may include multiple oxide regions, each of the multiple oxide regions corresponding to one of the plurality of active regions 141. FIG. 3B schematically illustrates an oxygen distribution or oxygen gradient of the principal memory region 140 of FIG. 1. The principal memory region 140 is characterized by a monotonically varying oxygen ion concentration 220 across the multiple active regions 141. The oxygen concentration 220 decreases from the first active region 140a to the second active region 140b. The oxygen concentration 220 decreases from the second active region 140b to the first scavenger region 140c. The oxygen concentration 220 decreases from the first scavenger region 140c to the second scavenger region 140d. The principal memory region 140 is characterized by an oxygen gradient in a first direction 210, in which the first active region 140a has the highest oxygen concentration and the second scavenger region 140d has the lowest oxygen concentration among the multiple active regions 141. In the non-limiting example of FIG. 3B, the oxygen concentration 220 decreases along the first direction 210, in which the first direction 210 is defined to extend from the first electrode 110 to the second electrode 120. The first direction 210 may also be defined as extending from the first active region 140a to the fourth active region 140d (the second scavenger region).

The first active region 140a is formed with a first oxygen concentration 241. The second active region 140b is formed with a second oxygen concentration 242 that is lower than the first oxygen concentration 241. The first scavenger region 140c is formed with a third oxygen concentration 243 that is lower than the second oxygen concentration 242. The second scavenger region 140d is formed with a fourth oxygen concentration 244. The third oxygen concentration 243 is higher than the fourth oxygen concentration 244. Preferably, the third oxygen concentration 243 is near-zero, and the fourth oxygen concentration 244 is zero.

A first interface 143a may be defined between the first active region 140a and the second active region 140b. The first interface 143a may be characterized by a first oxygen gradient, in which the first oxygen gradient corresponds to a difference between the first oxygen concentration 241 and the second oxygen concentration 242. A second interface 143b may be defined between the second active region 140b and the first scavenger region 140c. The second interface 143b may be characterized by a second oxygen gradient, in which the second oxygen gradient corresponds to a difference between the second oxygen concentration 242 and the third oxygen concentration 243. A third interface 143c may be defined between the first scavenger region 140c and the second scavenger region 140d. The third interface 143c may be characterized by a third oxygen gradient, in which the third oxygen gradient corresponds to a difference between the third oxygen concentration 243 and the fourth oxygen concentration 244. The second oxygen gradient is configured to be steeper than at least one of the first oxygen gradient and the third oxygen gradient. Preferably, the second oxygen gradient is configured to be steeper than each of the first oxygen gradient and the third oxygen gradient.

The first oxygen concentration 241 and the second oxygen concentration 242 may define a first range 251 of oxygen concentrations. The third oxygen concentration 243 and the fourth oxygen concentration 244 may define a second range 252 of oxygen concentrations. The active regions 141 are formed with respective oxygen concentrations such that the second range 252 of oxygen concentrations is lower than the first range 251 of oxygen concentrations. In other words, the respective oxygen concentration value (or level) in any and all of the scavenger regions 140c, 140d is significantly lower than any of the oxygen concentration values (or levels) in the first active region 140a and the second active region 140b. The first range 251 of oxygen concentrations and the second range 252 of oxygen concentrations are non-overlapping and distinct from one another. The principal memory region 140 may be characterized by a monotonic oxygen profile 250 having at least (i) the first range 251 of oxygen concentrations over more than one active regions 141 and (ii) the second range 252 of oxygen concentrations over more than one active regions 141. The monotonic oxygen profile 250 may be characterized by a steep decrease 253 in oxygen concentration from the first range 251 of oxygen concentrations to the second range 252 of oxygen concentrations. That is, the change in oxygen concentration between the first range 251 and the second range 252 may alternatively be described as a step-wise change in oxygen concentration that is more significant than a change in the oxygen concentration between other immediately adjacent active regions 141.

The principal memory region 140 includes three oxide sub-regions 140a, 140b, and 140c and one metal sub-region 140d. Each of the oxide sub-regions may be a material selected from the same oxide group. Alternatively, the oxide sub-regions may be different materials selected from different oxide groups. To achieve a desired oxygen profile 250, one or more dopants may be introduced to one or more of the oxide sub-regions 140a, 140b, and 140c. The dopant may be a metal element. For the sake of brevity, reference herein to an oxide sub-region being of a material (or being essentially of a material) does not preclude the oxide sub-region from having one or more dopants therein. For example, the first active region 140a may be a Ta oxide, the second active region 140b (or the first scavenger region 140c) may be a Ta oxide or another metal oxide, for example, Ti oxide or Hf oxide. Each of the first active region 140a and the second active region 140b may include one or more dopants in this example.

The switching compounds employed in the first active region 140a may be from a metal oxide. The first active region 140a includes or is essentially a second metal oxide formed with a near-stoichiometric material composition. In some embodiments, the second metal oxide may be formed with a stoichiometric material composition. The first active region 140a may include one of a tantalum (Ta) oxide, a titanium (Ti) oxide, a hafnium (Hf) oxide, a zirconium (Zr) oxide, a strontium (Sr) oxide, a lanthanum (La) oxide, a tungsten (W) oxide, a vanadium (V) oxide, or any combination thereof. In some examples, the second metal oxide is Ta₂Oₓ, in which x is a value in a range greater than 4 and smaller than 5 (i.e., 4<<<5). In some examples, the second metal oxide is Ta₂Oₓ, in which x is a value in a range greater than 4 and smaller than or equal to 5 (i.e., 4<x≤5). In some examples, the second metal oxide is Ta₂Oₓ, in which x is a value in a range greater than or equal to 4 and smaller than or equal to 5 (i.e., 4≤x≤5).

The second active region 140b includes or is essentially a third metal oxide. The third metal oxide may include one of a Ta oxide, a Ti oxide, a Hf oxide, a Zr oxide, a Sr oxide, a La oxide, a W oxide, a V oxide, or any combination thereof, in which the third metal oxide is selected to have a lower oxygen concentration than the second metal oxide. In some examples, the third metal oxide is TaO_{y}, in which y is a value in a range greater than 1.5 and smaller than x/2 (i.e., 1.5<y<x/2). In some preferred embodiments, the second metal oxide is TaO_{y}, in which y is a value in a range greater than 1.5 and smaller than or equal to 2.2 (i.e., 1.5<y≤2.2).

The third active region (i.e., the first scavenger region) 140c includes or is essentially a fourth metal oxide. The fourth metal oxide may include one of a Ta oxide, a Ti oxide, a Hf oxide, a Zr oxide, a Sr oxide, a La oxide, a W oxide, a V oxide, or any combination thereof, in which the fourth metal oxide is selected to have a lower oxygen concentration than the third metal oxide. In some examples, the fourth metal oxide is TaO_{z}, in which z is a value in a range greater than 0 (zero) and smaller than 0.5 (i.e., 0<z<0.5). In some preferred embodiments, the fourth metal oxide is TaO_{z}, in which z is a value in a range greater than 0 (zero) and smaller than or equal to 0.3 (i.e., 0<z≤0.3). The third active region 140c is selected such that the third oxygen concentration 243 characterizing the third active region 140c is greater than that of an active metal (non-oxide material). In preferred embodiments, the third active region 140c is selected such that the third oxygen concentration 243 is near-zero relative to a zero fourth oxygen concentration 244. In the present context, a near-zero oxygen concentration may refer to 0<z<0.5, where z is the ratio of oxygen ions to metal ions in the third active region 140c. In preferred embodiments, a near-zero oxygen concentration may refer to 0<z≤0.3, where z is the ratio of oxygen ions to metal ions in the third active region 140c.

The fourth active region (i.e., the second scavenger region) 140d may be formed of an active metal. Preferably, the active metal is selected to have a work function that is smaller than that of the second electrode material. The second scavenger region 140d may include or be essentially formed of at least one of Ta, Ti, Hf, Zr, cobalt (Co), nickel (Ni), iron (Fe), or any alloy thereof. The fourth active region 140d is characterized by the fourth oxygen concentration 244, in which the fourth oxygen concentration 244 may be zero.

The buffer region 130 is formed of a first metal oxide. The first metal oxide may be selected from a compound oxide which has a larger band gap than that of the first active region 140a. For example, in one embodiment in which the first active region 140a is a Ta oxide, the buffer region 130 may be one or a combination of Al₂O₃, MgO or SiO₂. In some embodiments, the first metal oxide includes at least one of MgO, AlOₓ₁, SiOₓ₁, CaO, LaAlO₃, HfSiOₓ₁, or any combination thereof. In some preferred embodiments, the first metal oxide is an aluminum oxide AlOₓ₁ in which x1 is 1.5. In some embodiments, the first metal oxide may be a non-stoichiometric, i.e., AlOₓ₁ in which x1 is a value in a range of 1<x1≤1.5. In some embodiments, the first metal oxide includes SiOₓ₁, in which x1 is a value in a range 1<x1≤2. In other embodiments, the first metal oxide includes HfSiOₓ₁, in which x1 is a value in a range 2≤x1≤4. In yet other embodiments, the first metal oxide is a mixture of MgO and AlOₓ₁, in which x1 is 1.5. In the non-volatile memory device 100 of the present disclosure, the buffer region 130 contributes towards preventing or reducing the interaction between the first electrode 110 and the principal memory region 140. When the stack 100 of the present disclosure is placed under an electrical field, the buffer region 130 may be more stable than the principal memory region 140, in terms of a greater interatomic bonding energy. Together with the rest of the stack configuration, the buffer region 130 contributes towards improvement in the reliability of continuous switching operations of the stack 100 over conventional stacks.

The first electrode 110 is made of a first electrode material. The first electrode may be one of a metal, a metal alloy, and a conductive nitride. Examples of the first electrode material include but are not limited to at least one of platinum (Pt), palladium (Pd), gold (Au), Al, W, Cu, molybdenum (Mo), Co, Ni, Fe, iridium (Ir), ruthenium (Ru), rhodium (Rh), titanium nitride (TiN), tantalum-tungsten (TaW), and tantalum nitride (TaN) etc. That is, the first electrode may include at least one of Pt, Pd, Au, Al, W, Cu, Mo, Co, Ni, Fe, Ir, Ru, Rh, TiN, TaW, and TaN.

The second electrode layer 120 is made of a second electrode material, in which the second electrode material may be a noble metal or a conductive material which shows oxidation resistance. Examples of the second electrode material include but are not limited to at least one of Pt, Pd, Au, Ir, Ru, Rh, TiN, and TaN, etc. That is, the second electrode may include at least one of Pt, Pd, Au, Ir, Ru, Rh, TiN, and TaN.

A thickness of respective ones of the first electrode 110 and the second electrode 120 may be in a range of from 1 nanometer (nm) inclusive to 100 nm inclusive. For the buffer region 130, the film thickness may be in a range from 0.5 nm inclusive to 5 nm inclusive. For the principal memory region 140, the respective film thickness 114a, 114b, 114c, and 114d of each active region 140a, 140b, 140c and 140d may be in a range of from 1 nm inclusive to 10 nm inclusive.

According to one example, the first active region 140a may be from Ta₂Oₓ, wherein 4<x<5; the second active region 140b may be from TaO_{y}, wherein 1.5<y<x/2; the first scavenger region 140c may be from TaO_{z}, wherein 0<z<0.5, and the second scavenger region 140d may be from Ta. For example, the non-volatile memory device 100 may have the following stack configuration: W/Al₂O₃/Ta₂Oₓ/TaO₂/TaO_{z}/Ta/Pt. In this stack configuration, the first electrode 110 is W, the second electrode 120 is Pt, and the buffer region 130 is Al₂O₃. The first active region 140a is Ta₂Oₓ, in which x is a value close to 5 such that Ta₂Oₓ is near stoichiometric. The second active region 140b is TaO₂, the first scavenger region 140c is TaO_{z}, and the second scavenger region 140d is Ta. The stack 100 is characterized by a relatively stable oxygen gradient, i.e., a relatively stable oxygen profile 250 which corresponds to a monotonically decreasing oxygen concentration from the first active region 140a to the second scavenger region 140d (along the first direction 210).

According to another example, the present disclosure provides a non-volatile memory device 100 characterized by a relatively stable oxygen distribution such that the non-volatile memory device 100 is able to sustain an oxygen gradient or an oxygen profile 250 that varies monotonically across the principal memory region 140. The buffer region 130 may include Al₂O₃. It was found that the stack configuration of the present disclosure is characterized by a relatively high level of stability such that the stack 100 can sustain a first active region 140a with stoichiometric tantalum oxide therein. That is, the example includes a buffer region 130 of Al₂O₃ and a first active region 140a of includes Ta₂Oₓ in which 4.5≤x≤5.

In some examples, the first active region 140a includes Ta₂Oₓ in which 4.5≤x≤5; the second active region 140b includes TaO_{y} in which 1.5≤y≤2.2; and the first scavenger region 140c includes TaO_{z} in which 0<z≤0.3.

In some preferred embodiments, the first electrode 110 includes W, the buffer region 130 includes Al₂O₃, the first active region 140a includes Ta₂O₅, the second active region 140b includes TaO₂, the second scavenger region 140d comprises Ta, and the second electrode 120 comprises Pt, and the first scavenger region 140c includes TaO_{z} in which 0<z≤0.3.

Preferably, when the first active region 140a and the second active region 140b both include oxides from the same group (i.e., oxides of metals from the same periodic group), the second active region 140b is doped with a first dopant. The first dopant is selected to be a metal different from any metal present in the first active region 140a. For example, the second active region 140b may include TaO_{y} in which 1.5≤y≤2.2, and in which the second active region 140b is doped with a first dopant, the first dopant being a metal different from any metal present in the first active region 140a. Preferably, the first scavenger region 140c comprises TaO_{z} in which 0<z≤0.3, and in which the first scavenger region 140c is doped with a second dopant, the second dopant being a metal different from any metal present in the first active region 140a. The second dopant may be the same or different to the first dopant. In some embodiments, the second dopant may be a metal that is the same as any one metal present in the second active region 140b, and in some embodiments the second dopant may be a metal different from any metal present in the second active region 140b. For example, each of the first active region 140a and the second active region 140b may include an oxide of a same group, in which the second active region 140b is one of an undoped third metal oxide and a doped third metal oxide, and in which the doped third metal oxide is doped with a first dopant, the first dopant being a metal different from a metal element of the oxide of the first active region 140a. The first dopant may be at least one metal selected from the group consisting of: Al, Hf, Ti, Zr, Nb, and Ru.

In some examples, each of the second active region 140b and the first scavenger region 140c may include an oxide of a same group (i.e., oxides of metals from the same periodic group), in which the first scavenger region 140c is one of an undoped fourth metal oxide and a doped fourth metal oxide, and in which the doped fourth metal oxide is doped with a second dopant, the second dopant being a metal different from a metal element of the oxide of the first active region 140a. In some embodiments, the second dopant may be a metal that is the same as any one metal present in the second active region 140b, and in some embodiments the second dopant may be a metal different from any metal present in the second active region 140b. The second dopant may be at least one metal selected from the group consisting of: Al, Hf, Ti, Zr, Nb, and Ru.

The stack configuration of FIG. 1 described above is found to advantageously facilitate control the oxygen profile 250 across the principal memory region 140 and improve the performance of non-volatile memory device 100. A relatively high degree of stability with relatively low power requirements was achieved experimentally with such a stack 100. This suggests that the non-volatile memory 100 of the present disclosure is able to achieve stable switching conditions, even after a high thermal budget process. In contrast, conventional stacks are known to exhibit interface reaction and diffusion that lead to re-configuration of the oxygen distribution across the regions. Such interface reactions and diffusion are especially pronounced at elevated temperatures in conventional stacks. For such reasons, the conventional stack may have a thermal budget that is too low for it to be used in various embedded applications. The stack configuration according to one embodiment of the present disclosure (e.g., W/Al₂O₃/Ta₂Oₓ/TaO_{y}/TaO_{z}/Ta/Pt) is characterized by a higher thermal budget compared to a control (e.g., W/Al₂O₃/Ta₂Oₓ/TaO₂/Ta/Pt). The thermal budget corresponds to a tolerance of the stack 100 for elevated temperatures. A higher thermal budget refers to a stack configuration that is able to sustain its switching performance even after undergoing elevated temperatures (such as those in semiconductor BEOL processes of around 400 degrees Celsius (° C.) and above).

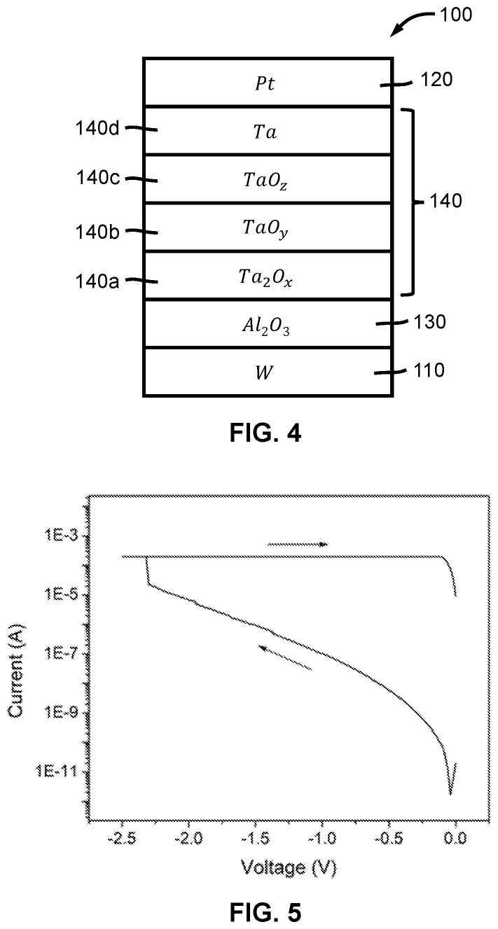

With regard to the embodiment shown in FIG. 4, FIG. 5 is a graph showing an exemplary current-voltage electroforming characteristic of a non-volatile memory device 100 with a W/Al₂O₃/Ta₂Oₓ/TaO₂/TaO_{z}/Ta/Pt stack structure according to embodiments of the present disclosure, in which z is near zero and not zero. The non-volatile memory device 100 was subjected to a post annealing treatment (400° C. for 30 minutes, followed by 375° C. for 2 hours) after the non-volatile memory device 100 was fabricated at room temperature. As shown in FIG. 5, a negative voltage was applied to the Pt electrode (second electrode 120), and the W electrode (first electrode 110) was grounded. When the voltage increased to around −2.3 V, a sudden increase of current was observed. This sudden increase in the current is indicative that the annealed stack was still operable and that an electroforming process through which conductive filaments or channels may be formed. A compliance current 1E-4 amperes (A) was used during the forming process. The stack configuration proposed herein was able to sustain up to 600° C. without losing its switching behavior. In other words, the stack configuration of the present disclosure has been experimentally verified to have a sufficiently high thermal budget capable of sustaining an operable stack after the post annealing treatment.

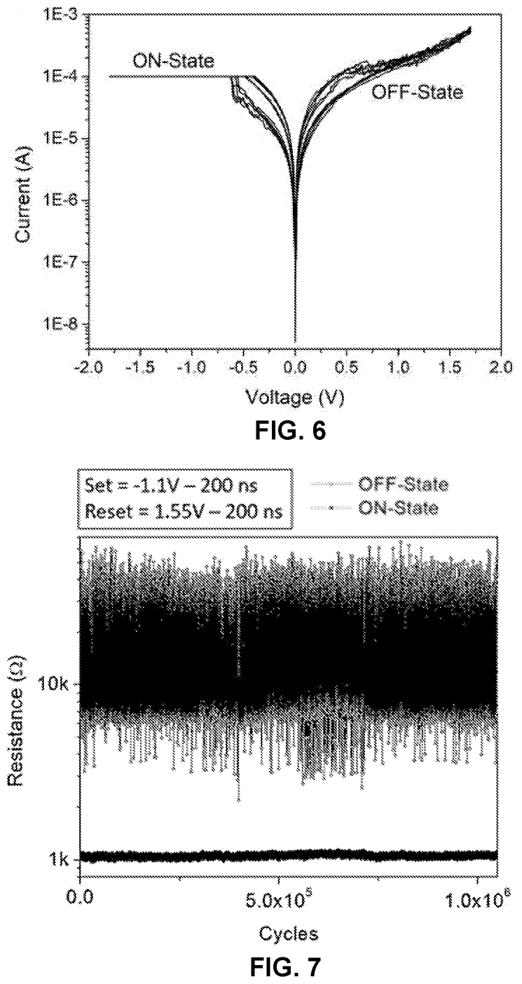

FIG. 6 shows the current-voltage curves of the non-volatile memory device 100 after the electroforming process shown in FIG. 5. The non-volatile memory device 100 was subjected to a continuously sweeping voltage between −1.8 volts (V) and 1.7 V, i.e., the resistance state of the non-volatile memory device 100 was repeatedly changed between an OFF-state (an HRS) and an ON-state (an LRS). To switch the non-volatile memory device 100 from an OFF-state to an ON-state, a negative SET voltage is required, while in the reverse process, that is, from an ON-state to an OFF-state, a positive RESET voltage is required. The experimental result shows that the magnitude of both the SET and RESET voltages are well below −1.0 V and 1.0 V, respectively. This result indicates that the stack 100 remains operable for low power device applications, i.e., the stack 100 has relatively low power requirements.

FIG. 7 shows a voltage pulse endurance test result of the non-volatile memory device 100 of FIGS. 5 and 6. The pulse endurance test was performed by applying positive and negative voltage pulses to switch the non-volatile memory device 100 to different resistance states in a sequential mode. To switch the non-volatile memory device 100 from an OFF-state (an HRS) to an ON-state (an LRS), a SET voltage pulse with a height of −1.1 V (pulse width of 200 nanoseconds (ns)) was used. In the reverse process, a RESET voltage pulse with a height of 1.55 V (pulse width of 200 ns) was used. The endurance test results shown in FIG. 7 demonstrates that the non-volatile memory device 100 can be repeatedly operated for over 1E6 times, i.e., over a million cycles. For context, a conventional stack (a control stack) typically has an endurance of about 100,000 cycles. The improvement in endurance of the present stack configuration is therefore on a scale of one order of magnitude. It suggests that the stack configuration of FIG. 4 can sustain a relatively more stable condition according to the desired oxygen profile 250 even after being subjected to a high temperature annealing process, and that the non-volatile memory device 100 can exhibit good reliability operable despite being exposed to elevated temperatures.

The non-volatile memory device 100 of FIG. 1 may be fabricated in a top-down or bottom-up method. For example, in FIG. 1, the first electrode layer 110 is a bottom electrode, followed in sequence by a buffer region 130 and a principal memory region 140, with the second electrode layer 120 as a top electrode. It will be understood that the non-volatile memory device 100 may be otherwise oriented. In other words, the second electrode layer 120 may be the bottom electrode, followed in sequence by the principal memory region 140 and the buffer region 130, with the first electrode layer 110 being the top electrode.

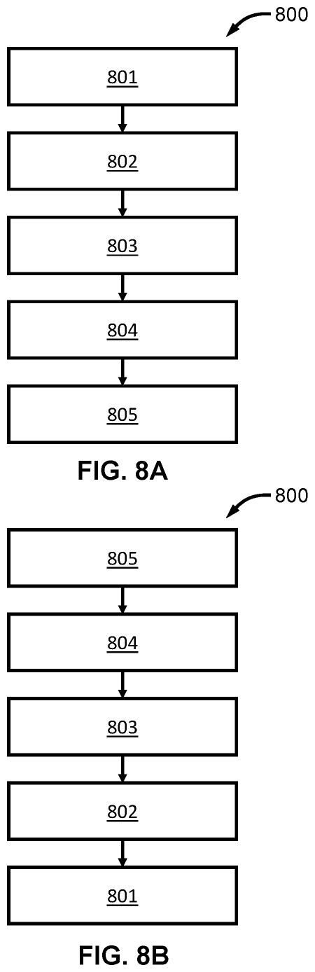

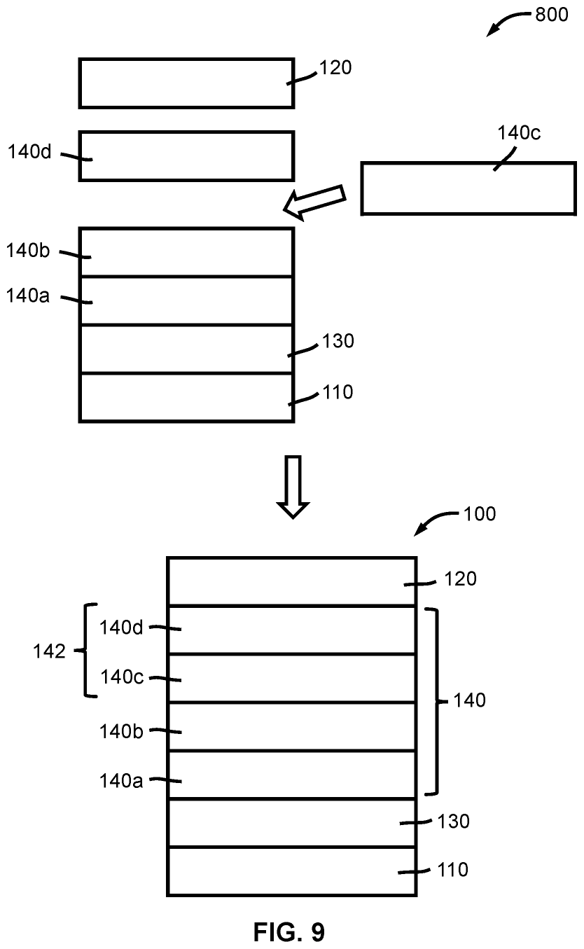

Embodiments of a method to fabricate the non-volatile memory device 100 of FIG. 1 will be described with reference to FIGS. 8A, 8B, and 9. As shown in the schematic flow chart of FIG. 8A, the method 800 includes the following steps: (1) forming the buffer region 130 on the first electrode 110 (801). The method 800 includes: (2) forming the principal memory region 140: (2-1) forming the first active region 140a and the second active region 140b (802,803), and (2-2) forming the two scavenger regions 140c, 140d (804,805). Through controlling the oxygen concentration of each active region 141, a principal memory region 140 composed of four active regions 141 with an oxygen gradient is formed between the first electrode 110 and the second electrode 120.

As shown in the schematic flow chart of FIG. 8B, the method 800 may show another flow chart which is based on forming a bottom electrode on a substrate. The method 800 includes forming the two scavenger regions 140d, 140c (805,804) on the bottom electrode, and then forming the second active region 140b and the first active region 140a (803,802), which is then followed by forming the buffer region 130 (801). The top electrode is then formed on the buffer region 130.

In other words, as shown in the schematic flow chart of FIG. 8A, the method 800 includes (i) disposing the second active region 140b (803) on the first active region 140a; and (ii) disposing the first scavenger region 140c (804) on the second active region 140b before disposing the second scavenger region 140d (805) on the first scavenger region 140c such that the principal memory region 140 is formed with four distinct regions 141 of different oxygen concentrations. Alternatively, the method 800 of FIG. 8B includes (i) disposing the first scavenger region 140c (804) on the second scavenger region 140d before disposing the second active region 140b (803) on the first scavenger region 140c; and (ii) disposing the first active region 140a (802) on the second active region 140b such that the principal memory region 140 is formed with four distinct regions 141 of different oxygen concentrations.

The materials for each active region 141 can be formed by any of a wide variety of conventional physical and chemical techniques. The techniques include but are not limited to sputtering, thermal evaporation, electron beam evaporation, chemical vapor deposition, etc. With the principal memory region 140 as an example, when a Ta₂O₅/TaO₂/TaO_{0.4}/Ta structure is selected for the stack, sputtering from a Ta target may be chosen to deposit each active region 141, with the fabrication conditions configured to achieve the desired structure for each active region 141. During the reactive sputtering process, the O/Ta ratio can be controlled through tuning the O₂/Ar gas flow ratio. To obtain a W/Al₂O₃/Ta₂O₅/TaO₂/TaO_{z}/Ta/Pt structure, where 0<z<0.5, the TaO_{z} region 140c may be inserted/deposited between TaO₂ (140b) and Ta (140d) regions to form a stepped oxygen profile 250 or a graduated oxygen gradient from Ta₂O₅ to Ta. Owing to the large oxygen concentration difference between the TaO₂ region and the TaO_{z} region, the TaO_{z} region also works as an oxygen scavenger layer. At the same time, the difference in oxygen concentration between the TaO₂ region and the Ta region is much smaller than that between TaO₂ and Ta. The TaO_{z} region prevents direct contact of the metal Ta region with the TaO₂ region, such that the insertion of the TaO_{z} region helps to alleviate the oxygen consumption from TaO₂, especially at high temperatures.

A robust stack configuration for a non-volatile memory device 100 and methods 800 of fabricating the non-volatile memory device 100 are provided in the foregoing. Based on the experimental test results, the stack configuration proposed herein presents a viable approach for the successful integration of memory cells with CMOS technology, including but not limited to embedded RRAM applications. The stack configuration proposed herein also demonstrates that it can control the oxygen ion or vacancy profile within the principal active region (i.e., within the main switching regions) such that the performance of the RRAM can be significantly improved over the conventional stack. One skilled in the art would appreciate that variations may be made to the exact material composition without departing from the scope or working principles of the present disclosure. For example, by depositing/inserting an oxygen scavenger region between an oxide region and a metal region (FIG. 9), the oxygen ion or vacancy concentration inside the immediately adjacent oxide region may be manipulated. The experimental results also show that the stack configuration proposed herein advantageously does not deteriorate in performance even where temperatures increase above room temperature.

All examples described herein, whether of apparatus, methods, materials, or products, are presented for the purpose of illustration and to aid understanding and are not intended to be limiting or exhaustive. Various changes and modifications may be made by one of ordinary skill in the art without departing from the scope of the invention as claimed.

1. A non-volatile memory device, comprising:
a first electrode;
a second electrode formed of a second electrode material;
a buffer region, the buffer region being disposed in direct contact with the first electrode; and
a principal memory region, the principal memory region being disposed between the second electrode and the buffer region, the principal memory region including:
a first active region, the first active region being disposed in direct contact with the buffer region, the first active region being formed with a first oxygen concentration;
a second active region, the second active region being formed with a second oxygen concentration that is lower than the first oxygen concentration;
a first scavenger region, the first scavenger region being formed with a third oxygen concentration that is lower than the second oxygen concentration; and
a second scavenger region, the second scavenger region being disposed in direct contact with the second electrode, the second scavenger region being formed with a fourth oxygen concentration,
wherein each of the second active region and the second scavenger region is disposed in direct contact with the first scavenger region, the second active region and the second scavenger region being formed physically spaced apart from one another.

2. The non-volatile memory device according to claim 1,
wherein a first interface between the first active region and the second active region is characterized by a first oxygen gradient, the first oxygen gradient corresponding to a difference between the first oxygen concentration and the second oxygen concentration, and wherein a second interface between the second active region and the first scavenger region is characterized by a second oxygen gradient, the second oxygen gradient corresponding to a difference between the second oxygen concentration and the third oxygen concentration, and wherein a third interface between the first scavenger region and the second scavenger region is characterized by a third oxygen gradient, the third oxygen gradient corresponding to a difference between the third oxygen concentration and the fourth oxygen concentration, and wherein the second oxygen gradient is configured to be steeper than at least one of the first oxygen gradient and the third oxygen gradient.

3. The non-volatile memory device according to claim 2,
wherein the second oxygen gradient is configured to be steeper than each of the first oxygen gradient and the third oxygen gradient.

4. The non-volatile memory device according to claim 1, wherein the first oxygen concentration and the second oxygen concentration define a first range of oxygen concentrations, and wherein the third oxygen concentration and the fourth oxygen concentration define a second range of oxygen concentrations, and wherein the second range of oxygen concentrations is lower than the first range of oxygen concentrations, and wherein the first range of oxygen concentrations and the second range of oxygen concentrations are non-overlapping and distinct from one another.

5. The non-volatile memory device according to claim 1, wherein the principal memory region is characterized by a monotonic oxygen profile having at least a first range of oxygen concentrations and a second range of oxygen concentrations, and
wherein the monotonic oxygen profile is characterized by a step decrease in oxygen concentration from the first range of oxygen concentrations to the second range of oxygen concentrations.

6. (canceled)

7. (canceled)

8. (canceled)

9. The non-volatile memory device as set forth in claim 1, wherein the buffer region is formed of a first metal oxide; and wherein the first metal oxide comprises at least one of MgO, AlOₓ₁, SiOₓ₁, CaO, LaAlO₃, HfSiOₓ₁, or any combination thereof.

10. The non-volatile memory device according to claim 1, wherein the first active region comprises a second metal oxide formed with a stoichiometric material composition or a near-stoichiometric material composition.

11. The non-volatile memory device according to claim 1, wherein the first active region comprises one of a Ta oxide, a Ti oxide, a Hf oxide, a Zr oxide, a Sr oxide, a La oxide, a W oxide, a V oxide, or any combination thereof.

12. The non-volatile memory device according to claim 1, wherein the first active region comprises Ta₂Oₓ in which 4<x<5.

13. The non-volatile memory device according to claim 1, wherein the second active region comprises a third metal oxide.

14. The non-volatile memory device according to claim 12, wherein the second active region comprises TaO_{y} in which 1.5<y<x/2.

15. The non-volatile memory device according to claim 1, wherein the first scavenger region comprises a fourth metal oxide.

16. The non-volatile memory device according to claim 1, wherein the first scavenger region comprises TaO_{z} in which 0<z<0.5.

17. (canceled)

18. The non-volatile memory device according to claim 1, wherein the second scavenger region comprises at least one of Ta, Ti, Hf, Zr, Co, Ni, Fe, or any alloy thereof.

19. (canceled)

20. (canceled)

21. (canceled)

22. (canceled)

23. (canceled)

24. (canceled)

25. The non-volatile memory device according to claim 1, wherein the first electrode comprises W, the buffer region comprises Al₂O₃, the first active region comprises Ta₂O₅, the second active region comprises TaO₂, the second scavenger region comprises Ta, and the second electrode comprises Pt, and wherein the first scavenger region comprises TaO_{z} in which 0<z≤0.3.

26. The non-volatile memory device according to claim 1, wherein the buffer region comprises Al₂O₃, and wherein the first active region comprises Ta₂Oₓ in which 4.5<x≤5.

27. The non-volatile memory device according to claim 26, wherein the second active region comprises TaO_{y} in which 1.5≤y≤2.2, and which the second active region is doped with a first dopant, the first dopant being a metal different from any metal present in the first active region.

28. The non-volatile memory device according to claim 27, wherein the first scavenger region region comprises TaO_{z} in which 0<z≤0.3, and wherein the first scavenger region is doped with a second dopant, the second dopant being a metal different from any metal present in the first active region.

29. (canceled)

30. (canceled)

31. (canceled)

32. (canceled)

33. A method of making the non-volatile memory of claim 1, the method comprising:
disposing the first scavenger region on the second scavenger region before disposing the second active region on the first scavenger region; and
disposing the first active region on the second active region such that the principal memory region is formed with four distinct regions of different oxygen concentrations.

34. A method of making the non-volatile memory of claim 1, the method comprising:
disposing the second active region on the first active region; and
disposing the first scavenger region on the second active region before disposing the second scavenger region on the first scavenger region such that the principal memory region is formed with four distinct regions of different oxygen concentrations.
